(19) United States
(12) Patent Application Publication
(10) Pub. No.: US 2011/0024876 A1
(43) Pub. Date: Feb. 3, 2011

(54) CREATION OF THIN GROUP II-VI MONOCRYSTALLINE LAYERS BY ION CUTTING TECHNIQUES

(75) Inventors: Robert W. BOWER, Anacortes, WA (US); Sivalingam SIVANANTHAN, Naperville, IL (US); James W. GARLAND, Aurora, IL (US)

Correspondence Address: Momkus McCluskey, LLC, 1001 Warrenville Road, Suite 500, Lisle, IL, 60532, US

(73) Assignee: EPIR TECHNOLOGIES, INC., Bolingbrook, IL (US)

(21) Appl. No.: 12/533,253

(22) Filed: Jul. 31, 2009

(51) Int. Cl. H01L 29/22; H01L 21/04

(52) U.S. Cl. 257/614; 438/458; 257/E29.094; 257/E21.04

(57) ABSTRACT

Expungement ions, preferably including hydrogen ions, are implanted into a face of a first, preferably silicon, substrate such that there will be a maximum concentration of the expungement ions at a predetermined depth from the face. Subsequently a monocrystalline Group II-VI semiconductor layer, or two or more such layers, is/are grown on the face, as by means of molecular beam epitaxy. After this a second, preselected substrate is attached to an upper face of the Group II-VI layer(s). Next, the implanted expungement ions are used to expunge most of the first substrate from a remnant thereof, from the grown II-VI layer, and from the second substrate. In another embodiment, a group II-VI layer is grown on a first substrate silicon and an ionic implantation is conducted such that a maximum concentration of expungement ions occurs either in the silicon substrate at a predetermined depth from its interface with the II-VI layer or in the first Group II-VI semiconductor layer at a predetermined depth from the top face of the Group II-VI semiconductor layer. Thereafter all of the first substrate is expunged from the rest of the workpiece. Thin monocrystalline Group II-VI semiconductor structures may thus be mounted to substrates of the fabricator's choice; these substrates may be semiconductors, integrated circuits, MEMS structures, polymeric, metal or glass, may be flexible and may be curved.

### BACKGROUND OF THE INVENTION

Single-crystal CdTe is a very useful semiconductor material for a variety of uses for optoelectronic devices such as solar cells, infrared detectors and cameras. On the other hand, single-crystal CdTe, like other single-crystal Group II-VI semiconductors, is very expensive and mechanically not very robust. For this reason the assignee of this invention has developed methods and structures for producing thin single-crystal CdTe on silicon. [1,2] This helps reduce cost, as a silicon substrate is much less expensive than other substrates that have been used as CdTe hosts in the art. It has now been shown that II-VI semiconductor homojunctions grown on Si make extremely efficient relatively inexpensive multijunction solar cells. [3] The present invention discloses ways in which silicon can continue to be used as a host for growing a CdTe layer, but in which the silicon substrate can either be greatly reduced or entirely omitted in the final semiconductor structure using the ion-cut technology. [4, 5] For solar cell applications as an example, removing the silicon substrate allows the growth of a homojunction with optimal bandgap on the newly exposed CdTe surface, allows the solar cell to be made flexible, to be lighter for space applications and to have a lower series resistance.

### SUMMARY OF THE INVENTION

According to a first ion cut manufacturing process according to the invention, expungement ions, which may include hydrogen, helium or other suitable ions, are implanted into a first face of a first substrate, which can be monocrystalline silicon. The energy and dose of the implant are selected such that a maximum concentration of the expungement ions occurs at a predetermined depth from the first face of the substrate. Thereafter a thin Group II-VI monocrystalline semiconductor layer, such as one comprising CdTe, is grown as by means of molecular beam epitaxy on this face.

After this, a second, preselected substrate, which could be any of a number of materials including semiconductors, integrated circuits, microelectromechanical system (MEMS) structures, polymers, metal and glass, is attached to an upper face of the II-VI semiconductor layer. After this attachment, a portion of the first substrate is expunged from the workpiece. The portion expunged extends from the predetermined depth (at which the maximum concentration of implanted expungement ions occurs) to a second face or bottom of the substrate. Expungement can be the result of either heating the first substrate, or creating a mechanical strain on the substrate at the aforementioned predetermined depth, and in a plane parallel to the first face of the first substrate.

After expungement a remainder of the first substrate will still adjoin the Group II-VI semiconductor layer. This remainder can be removed as by means of chemical or plasma etching or chemical-mechanical polishing, or may be kept in place and used in fabricating e.g. monocrystalline silicon components of integrated circuits or devices. These devices can also incorporate nonsilicon structures formed from the Group II-VI layer underneath. It is possible to mask and then selectively remove portions of the remnant of the first substrate. Selective removal can for example create discrete nucleation sites for further growth of monocrystalline Group II-VI semiconductor structures.

In a variation of the first process, after the Group II-VI semiconductor layer is grown, a highly conductive layer such as a heavily doped semiconductor, tunnel junction structure, silicide or metal is appended to its upper face. The highly conductive layer is used to attach the Group II-VI semiconductor layer to the second substrate. Most of the first substrate is expunged, as before.

The second substrate can be preselected to be a flexible layer.

In a second ion cut manufacturing process according to the invention, in a first step a monocrystalline Group II-VI semiconductor layer is grown on a first substrate, and in a subsequent step, expungement ions, which may include hydrogen, helium and/or other suitable ions, are implanted through the Group II-VI semiconductor layer and into the first substrate. Once again the implantation energy and dose are selected such that a maximum concentration of the expungement ions will occur at a predetermined depth in the first substrate from its first or upper face. Then, one or more additional layers of Group II-VI semiconductor layers may be added to the first substrate. After this a preselected second substrate is attached to an upper, second face of the Group II-VI semiconductor layer. Next, a portion of the first substrate, extending from the predetermined depth to a second face of the first substrate, is expunged, leaving a portion of the first substrate behind. As before, this remnant may be removed or may be used to form components of an integrated circuit that also has structures formed from the Group II-VI semiconductor layer.

In a variation of the second manufacturing process, after the implantation step a highly conductive layer such as a heavily doped semiconductor, tunnel junction structure, silicide or metal is deposited on the second, upper face of the Group II-VI semiconductor layer. This highly conductive layer is then appended to an upper face of the Group II-VI semiconductor layer to the second, preselected substrate. As before, the second substrate can be preselected to be flexible.

In a third manufacturing process according to the invention, a monocrystalline layer of Group II-VI semiconductor material, such as CdTe, is grown on a first face of a first substrate, which can be monocrystalline silicon. Next, an expungement ion implantation step is performed in which the expungement ions may include hydrogen, helium and/or other suitable ions. A dose and implantation energy are selected such that a maximum concentration of the ions occurs at a predetermined depth in the Group II-VI semiconductor layer rather than in the supporting first substrate. Again, in this case, one or more additional layers of Group II-VI semiconductor may be added to the first substrate. After these steps, a second, preselected substrate (which can be chosen to be flexible) is attached to an upper or second face of the Group II-VI semiconductor layer. Then an expungement step is performed, removing a portion of the Group II-VI semiconductor layer from the predetermined depth to the first face thereof, and removing all of the first substrate with it.

In a variation of the third manufacturing process, after the implantation step and any additional II-VI semiconductor layer is added, a highly conductive hydrophilic layer is deposited on the second or upper face of the Group II-VI semiconductor layer. This highly conductive layer is then used to attach the Group II-VI semiconductor layer to the second, preselected substrate, which may be preselected to be flexible.

In each of the above processes, the first substrate can be chosen to be elemental silicon, an alloy of silicon and germanium, a silicon-on-insulator (SOI) structure, a Group II-VI compound semiconductor, or a Group III-V compound semiconductor. The grown monocrystalline Group II-VI semiconductor layer can be chosen as CdTe, CdₓZn₁₋ₓTe(0<x<1) or any other binary, ternary or quaternary Group II-VI semiconductor, and its composition may be graded as a function of depth or it may be a multilayer of these semiconductor species. The implanted expungement ions can be selected from the group consisting of H, He, other appropriate ions and mixtures thereof. The expungement step may be performed by heating the layer in which the maximum concentration of ions occurs, or alternatively may be performed by creating a mechanical strain on the workpiece, at the predetermined depth, and in a plane parallel to the upper face of the Group II-VI semiconductor layer.

Each of the above processes produces a mounted semiconductor structure in which a thin monocrystalline Group II-VI layer is mounted to a substrate that can be chosen to be any of a number of things, including semiconductors, integrated circuits, MEMS structures, a carbon- or silicone-based polymer, metal or glass, the choice not being constrained by the second substrate's suitability as a growth or deposition site for the Group II-VI semiconductor material. Advantageously this second substrate can be chosen to be a polymer and can be chosen to be flexible, and may be planar or concavely or convexly curved. In some embodiments the mounted semiconductor structure will include a highly conductive layer interposed between the new substrate and the Group II-VI semiconductor layer, while in other embodiments the Group II-VI semiconductor layer will be mounted directly to the new substrate. The mounted Group II-VI semiconductor structures according to the invention are particularly suited for forming photovoltaic or other optoelectronic devices.

### BRIEF DESCRIPTION OF THE DRAWINGS

Further aspects of the invention and their advantages can be discerned in the following detailed description, in which like characters denote like parts and in which:

FIGS. 1A-1E are highly magnified schematic cross-sectional views of a semiconductor workpiece, illustrating successive stages of a first process according to the invention;

FIGS. 2A-2F are highly magnified schematic cross-sectional views of a second semiconductor workpiece, illustrating successive stages of a variation of the process shown in FIGS. 1A-1E;

FIGS. 3A-3E are highly magnified schematic cross-sectional views of a third semiconductor workpiece, illustrating successive stages of a second process according to the invention;

FIGS. 4A-4C are highly magnified schematic cross-sectional views of a fourth semiconductor workpiece, illustrating successive stages of a variation of the process shown in FIGS. 3A-3E;

FIGS. 5A-5C are highly magnified schematic cross-sectional views of a fifth semiconductor workpiece, illustrating successive stages of a third process according to the invention;

FIGS. 6A-6D are highly magnified schematic cross sectional view of a sixth semiconductor workpiece, illustrating successive stages of a variation of the process shown in FIGS. 5A-5C;

FIGS. 7A and 7B are highly magnified schematic partial cross-sectional views of Group II-VI monocrystalline semiconductor layers as mounted on curved substrates;

FIGS. 8A-8E are highly magnified schematic cross-sectional views illustrating a variation on the process shown in FIGS. 3A-3E, in which an additional Group II-VI semiconductor layer is formed after an expungement ion implantation step;

FIGS. 9A-9D are highly magnified schematic cross-sectional views illustrating a variation on the process shown in FIGS. 4A-4C, in which an additional Group II-VI semiconductor layer is formed after an expungement ion implantation step;

FIGS. 10A-10D are highly magnified schematic cross-sectional views illustrating a variation on the process shown in FIGS. 5A-5C, in which an additional Group II-VI semiconductor layer is formed after an expungement ion implantation step;

FIGS. 11A-11E are highly magnified schematic cross-sectional views illustrating a variation shown in FIGS. 6A-6D, in which an additional Group II-VI semiconductor layer is formed after an expungement ion implantation step; and

FIGS. 12A-12B are highly magnified schematic partial cross-sectional views of multiple Group II-VI semiconductor layers as mounted on complexly curved substrates.

### DETAILED DESCRIPTION

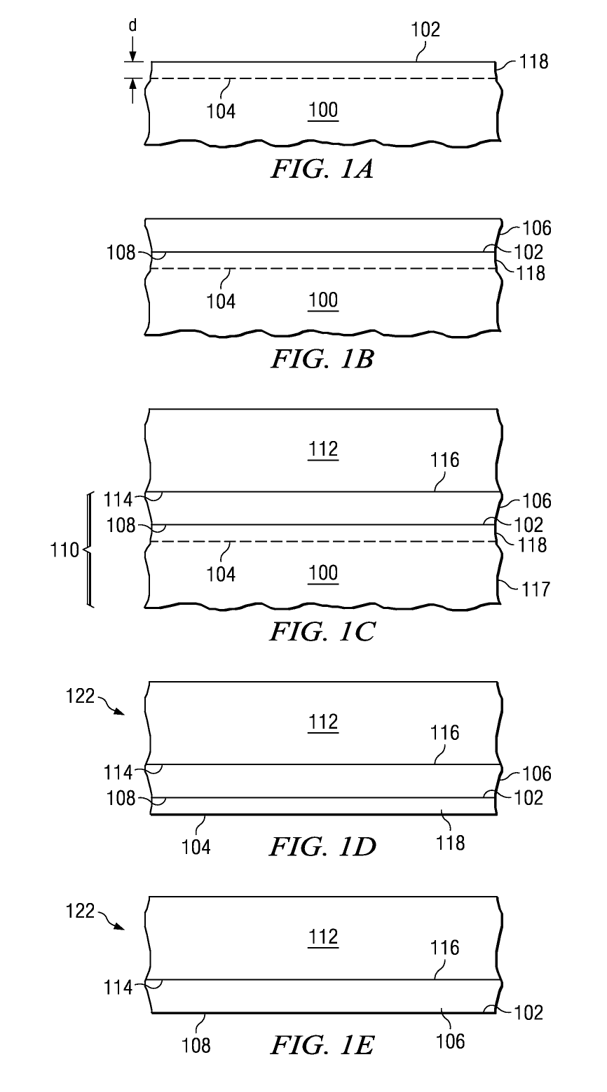

Referring first to FIGS. 1A-1E, successive steps in a first ion cut process according to the invention are illustrated. A first, preselected substrate 100 is provided, which can be made of a relatively inexpensive material such as elemental silicon. Alternatively the first substrate can be another Group IV monocrystalline substrate, such as an alloy of Silicon and Germanium, or a silicon on insulator (SOI) structure in which a silicon portion is uppermost as appears in these FIGUREs. The substrate 100 can also consist or comprise a Group III-V semiconductor or a Group II-VI semiconductor. The substrate 100 should be thick enough to be mechanically robust and successfully resist degrading forces placed upon it during the rest of the process steps described herein, including mechanical, chemical and thermal treatments encountered in semiconductor processing. An upper surface 102 of the substrate 100 may be chosen to be in a plane which will present a crystalline structure which will best match the crystalline structure of the Group II-VI semiconductor layer to be formed on it later.

As a first process step an expungement ion implantation is performed through an upper surface 102 of the substrate 100. The implanted expungement ions are of one or more species that, as implanted and when subjected to a triggering change in their environment such as an increase in temperature or the creation of mechanical strain, will act to expunge the semiconductor layer on one side of them from the layer on the other side. The expungement ions may consist of or comprise hydrogen, helium, and/or other suitable ions. The dose and implantation energy of the implantation are selected such that the concentration of implanted expungement ions achieves a maximum at a depth d, predetermined by the fabricator, below surface 102. The depth d can be chosen from the range of about 100 nm to about 5,000 nm. A horizon or level 104 at depth d is represented by a dotted line and is roughly parallel to the substrate surface 102. The implantation energy can be chosen from the range of about 10 keV to about 300 keV. The implantation dose can be selected from the range of about 1×10¹⁶ ions/cm² to about 3×10¹⁷ ions/cm². The dose is selected such that the thin layer of the first substrate will not be expunged during the subsequent growth of monocrystalline Group II-VI semiconductor layer 106, but such that it will cause the expungement of most of the first substrate later.

Referring to FIG. 1B, a monocrystalline Group II-VI semiconductor layer 106 is formed on the upper face 102 of the substrate 100. The Group II-VI layer may be formed by metal organic chemical vapor deposition (MOCVD), liquid phase epitaxy (LPE), or other means but it is preferred to form the Group II-VI layer by molecular beam epitaxy (MBE). The Group II-VI monocrystalline layer 106 can be chosen to be CdTe or CdₓZn₁₋ₓTe (0<x<1) (commonly abbreviated as “CdZnTe”) or other Group II-VI semiconductor. Particularly as using MBE, the composition of layer 106 can be varied or graded as the semiconductor material is deposited. For example, layer 106 may start out as CdTe at its lower or first surface 108, and thereafter may be gradually changed to a ternary or even quaternary Group II-VI semiconductor, and then further altered thereafter. At surface 108, layer 106 advantageously may be selected as CdTe to achieve an optimal energy gap. After this initial sublayer, the composition of the Group II-VI layer may be varied to satisfy desired performance characteristics of the layer 106. Portions of the Group II-VI layer may, for example, be composed of CdS, CdSe, CdTe, ZnTe, ZnS, CdSeTe, CdZnTe, CdMnTe, CdMgTe, CdHgTe and graded composites or multilayers of the foregoing, may be doped (or not) as desired to be (p) type, (n) type, or intrinsic, and may form structures such as photovoltaic cells or subcells, tunnel junctions between such subcells, infrared detector cells and the like. Alternatively, layer 106 may be chosen to be a Group II-VI “seed” layer providing one or more nucleation sites for a later growth of Group II-VI material after the process steps illustrated here.

Layer 106 may be grown to a predetermined thickness, such as in the range of 40 nm to 1000 nm. Advantageously the present invention permits the transfer of a very thin monocrystalline layer of Group II-VI semiconductor material to a second substrate that may be selected for characteristics other than its efficacy as a nucleation site or beginning host for the Group II-VI semiconductor material.

Referring next to FIG. 1C, workpiece 110, including at this point layer 106 and substrate 100, is attached to a second substrate 112. The Group II-VI semiconductor layer 106, as-grown, has a second or upper face 114, and this is attached to a face 116 of the second substrate 112. The method of attachment can range from fusion bonding to various highly conductive metallic adhesives as are known in the bonding art. One of the advantages of the invention inheres in the fact that the substrate 112 may be composed of any of a wide variety of substances, including semiconductors, integrated circuits, MEMS structures, carbon- or silicone-based polymers, metal or glass, and further more doesn't even have to be rigid, or even planar. Particularly where the layer 106 is chosen to be sufficiently thin, the resulting mounted semiconductor structure can be curved and/or can have a measure of flexibility.

The structure seen in FIG. 1C is then subjected to an expungement step. This can either occur by heating at least layer 100 to a temperature sufficient to cleave layer 100 along plane 104, or by creating a mechanical strain along plane 104. Where heating is chosen as the expungement methodology, the temperature should be selected to be sufficiently high to expunge that major portion 117 of the substrate 100 that extends below plane 104, but not so high that the Group II-VI semiconductor layer will be adversely affected. This temperature, for example, can be selected to be in the range of about 300° C. to about 450° C.

The result of the expungement step is shown in FIG. 1D. A large portion of the first substrate 100 is expunged from a remaining first substrate portion 118, which continues to adhere to the Group II-VI semiconductor layer 106 and the second substrate 112. The remaining first substrate portion 118 may be left in place, where it can be fashioned into various MEMs, nanoelectronic or other integrated circuit structures, or (FIG. 1E) be removed as by means of wet or plasma etching or chemical-mechanical polishing to completely clear the first face 108 of the Group II-VI layer 106. Face 108 may then be used as a nucleation site for the growth of further Group II-VI material or may be processed into discrete optoelectronic or other integrated circuit components. Alternatively, the workpiece 122 shown in FIG. 1D may have substrate portion 118 only selectively removed, thereby exposing only portions of the surface 108. These portions can then be used as nucleation sites for discrete semiconductor cells. Portions of layer 118 could alternatively be used to self-align further processes (such as implantation or selective etching) on the selectively exposed Group II-VI layer 106.

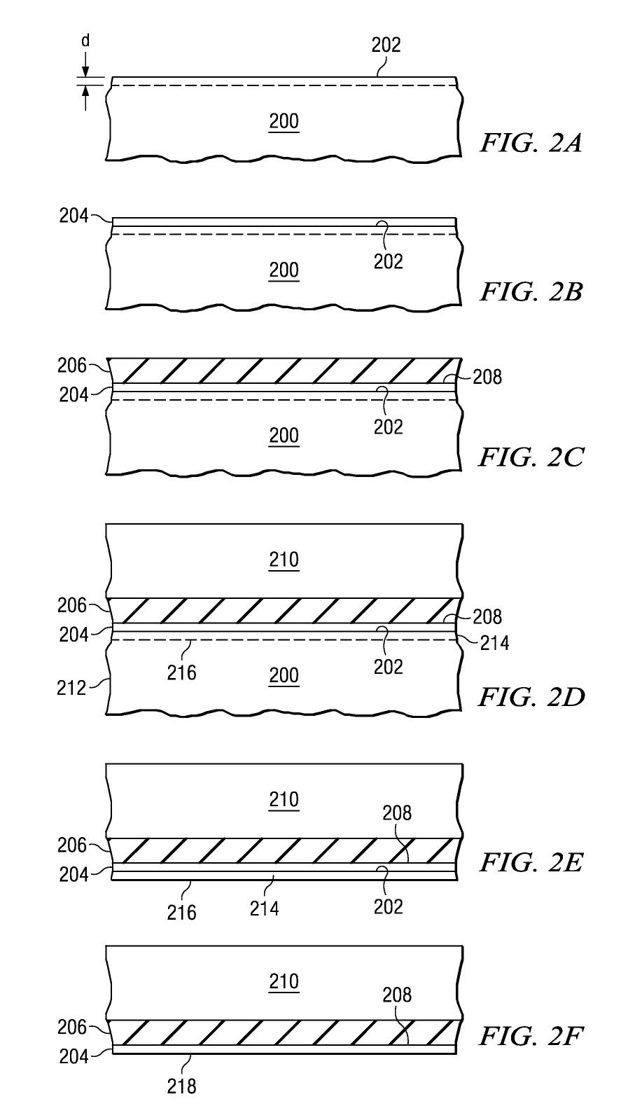

A variant of this first process is illustrated in FIGS. 2A-2F. A first substrate 200 is implanted as before with expungement ions, preferably consisting of or comprising hydrogen, helium, other suitable ions or mixtures thereof, such that a maximum concentration occurs at a preselected depth d from an upper surface 202. A monocrystalline Group II-VI semiconductor layer 204, having one of the compositions above described, is formed on the surface 202 (FIG. 2B). But instead of directly attaching to a second substrate, in FIG. 2C a highly conductive layer 206, such as a heavily doped semiconductor, tunnel junction structure, silicide or metal is appended to the upper surface 208 of the group II-VI semiconductor layer 204. Then, in FIG. 2D, a second substrate 210 is attached to the highly conductive layer 206. The layer 206 can aid in passivation or in bonding to the desired second substrate 210.

After layers 200-206 have been attached to the second substrate 210, an expungement operation is performed, cleaving a bottom portion 212 of the first substrate 200 from a top portion 214 thereof, portions 212 and 214 being separated by a plane or horizon 216 at which occurs a maximum concentration of the implanted expungement ions. The result is shown in FIG. 2E. Plane or horizon 216 now becomes a bottom face of the remnant first substrate portion 214.

As before, the e.g. silicon substrate portion 214 can be completely or partially left on Group II-VI semiconductor layer 204 and used for further processing of layer 214 and/or underlying layer 204 into integrated circuit structures. Alternatively, the remainder 214 can be stripped off as by means of wet or plasma etching or chemical-mechanical polishing, to yield the mounted Group II-VI semiconductor structure shown in FIG. 2F, wherein a bottom surface 218 of the layer 204 is completely exposed.

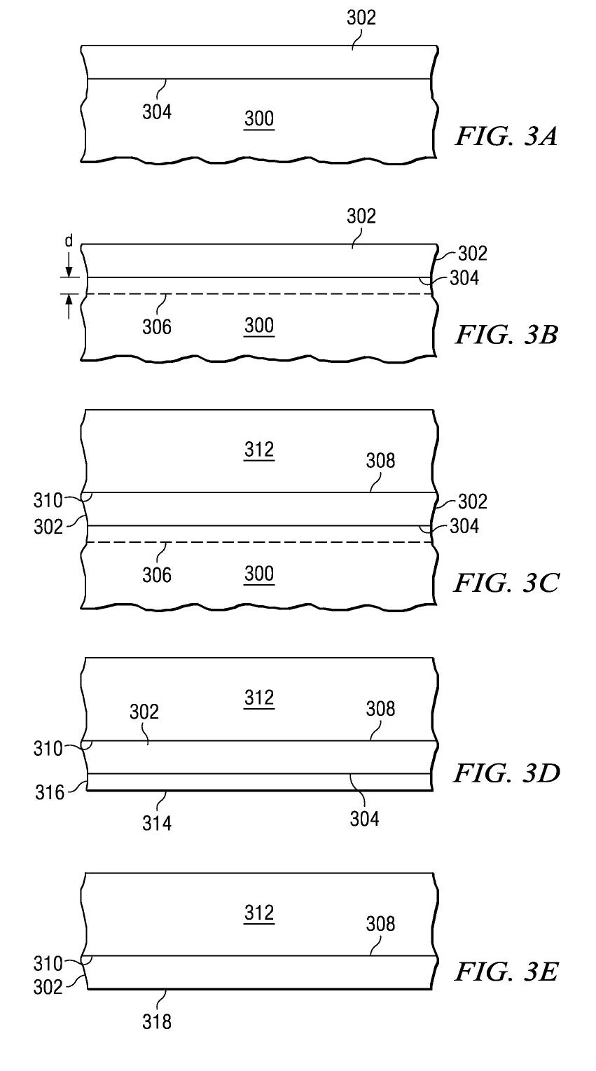

A second manufacturing process according to the invention is shown in FIGS. 3A-3E. In a first step of this embodiment a monocrystalline Group II-VI semiconductor layer 302, having any of several possible compositions as above described, is formed on an upper surface 304 of an e.g. monocrystalline silicon substrate 300. Substrate 300 can instead be SiGe or a silicon on insulator (SOI) structure, a Group II-VI compound semiconductor or a Group III-V compound semiconductor. Only after this are expungement ions, which can comprise H, He, other suitable ions or mixtures thereof, implanted completely through layer 302 and into substrate 300, such that a maximum ion concentration will occur at a plane or horizon 306, which is located at a predetermined depth d below the surface 304. All other factors being the same, this implantation will have to be carried out at a higher energy to obtain the same expungement ion concentration at the same depth. The depth d can be chosen in the range of 1,000 to 10,000 nm; the implantation energy can be chosen in the range of about 100 keV to about 1.1 MeV; and the dose can be chosen from the range of about 1×10¹⁶ ions/cm² to about 3×10¹⁷ ions/cm². This method allows more flexibility in dose without the danger that layer 316 will expunge during the growth of the Group II-VI semiconductor layer 302 thereon.

In FIG. 3C, an upper surface 308 of the Group II-VI semiconductor layer 302 is attached to a lower surface 310 of a second, preselected substrate 312. An expungement process is then performed, such that the horizon or plane 306 becomes a bottom surface 314 of a remnant first substrate portion 316 (FIG. 3D). As before, this substrate portion can be retained, or can be removed to produce a mounted Group II-VI semiconductor structure as shown in FIG. 3E, wherein a bottom surface 318 of the Group II-VI semiconductor layer 302 becomes exposed.

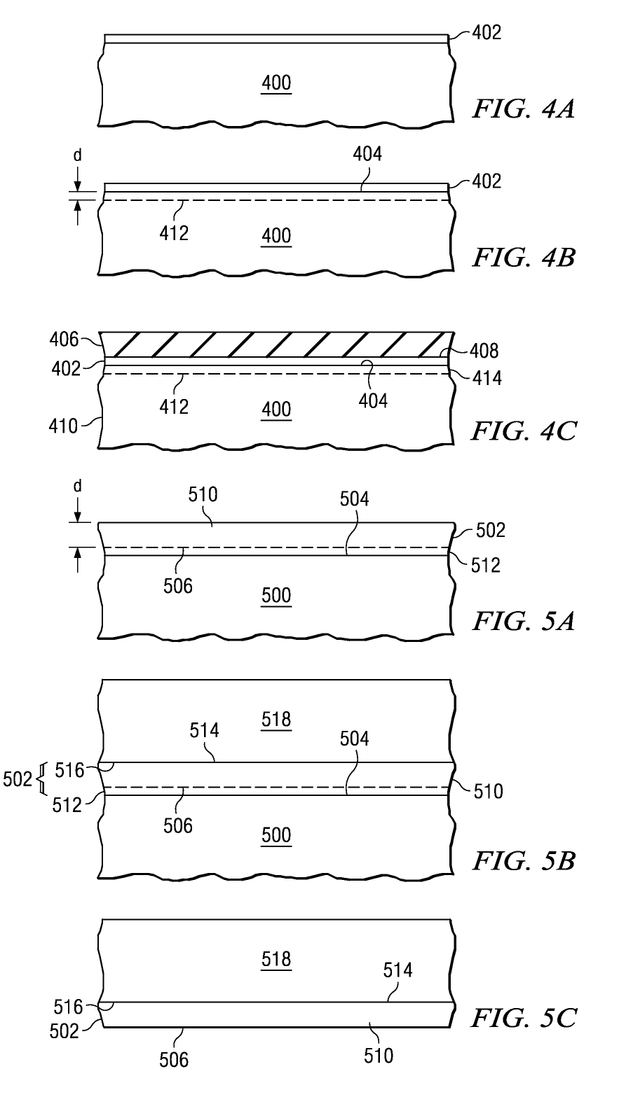

A variation of the second manufacturing process is shown in FIGS. 4A-4C. Therein, a first substrate 400, which can be monocrystalline silicon, has grown thereon a thin monocrystalline layer 402 of Group II-VI semiconductor material. After this step, and referring to FIG. 4B, an ion implantation occurs, in which expungement ions, preferably consisting of or comprising hydrogen, helium, other suitable ions or mixtures thereof, are implanted through the layer 402 into substrate 400. An implantation energy and dose are selected such that a maximum concentration of ions occurs at a predetermined depth d below an upper surface 404 of the first substrate 400.

After the implantation step and any additional group II-VI semiconductor layers are added to layer 402, and referring to FIG. 4C, a highly conductive layer 406, which can be a heavily doped semiconductor, tunnel junction structure, silicide or metal, is appended to the upper surface 408 of the Group II-VI semiconductor layer 402. The remaining process steps are similar to those shown in FIGS. 3C-3E. The highly conductive layer 406 is used to attach the Group II-VI semiconductor layer 402 to a second, preselected substrate (not shown), and subsequent to this a major portion 410 of the substrate 400 is expunged from the remainder of the workpiece, cleaving along plane or horizon 412. A first substrate remnant 414 may subsequently be completely or partially removed or used in further processing, as previously described.

FIGS. 5A-5C illustrate a third fabrication process according to the invention. Referring to FIG. 5A, as in the other fabrication sequences described herein, a first substrate 500 is selected for its robustness, its low cost and the ease with which a monocrystalline Group II-VI semiconductor layer 502 may be grown on it. Monocrystalline silicon, alloys of silicon and germanium, silicon-on-insulator (SOI) structures, Group II-VI semiconductors and Group III-V semiconductors are possibilities. A single-crystal Group II-VI semiconductor layer 502, which may have any of various single, graded composite or multilayer compositions as above described in other process embodiments, is formed on an upper surface 504 of the first substrate 500 as by means of MBE or MOCVD. Following this deposition/growth step, an implantation operation occurs, in which expungement ions, which preferably comprise hydrogen, helium, other suitable ions or mixtures thereof, are implanted at a dose and energy level such that a maximum concentration will occur at a predetermined depth d in the Group II-VI semiconductor layer 502, at plane or horizon 506, which is roughly parallel to an upper surface 514 of the Group II-VI semiconductor layer 502 and which is spaced from a lower surface of the Group II-VI semiconductor layer 502. The depth d can be selected from the range of about 10 nm to about 5,000 nm. The expungement ion implantation dose can be selected from the range of about 1×10¹⁶ ions/cm² to about 3×10¹⁷ ions/cm². The implantation energy can be selected from the range of about 10 keV to about 1.1 MeV. Plane 506 divides the Group II-VI semiconductor layer into an upper portion 510 and a lower portion 512 that is attached to first substrate 500.

After the implantation step and any additional group II-VI semiconductor layers are added to layer 502 and as seen in FIG. 5B, an upper surface 514 of the semiconductor layer 502 is attached to a lower surface 516 of a preselected second substrate 518. The second substrate 518 can include, for example, semiconductors, integrated circuits, MEMS structures, a polymer, metal or glass. After this step an expungement is performed, such that all of substrate 500, and the lower portion 512 of Group II-VI semiconductor layer 502, are removed from the upper portion 510 of the Group II-VI semiconductor layer and the second substrate 518. The result is shown in FIG. 5C, wherein only the second substrate 518 and a thin portion 510 of the Group II-VI semiconductor layer 502 remain. Plane or level 506 becomes the lower, exposed surface of the Group II-VI semiconductor layer 502 as mounted to a substrate 518 of the fabricator's choice.

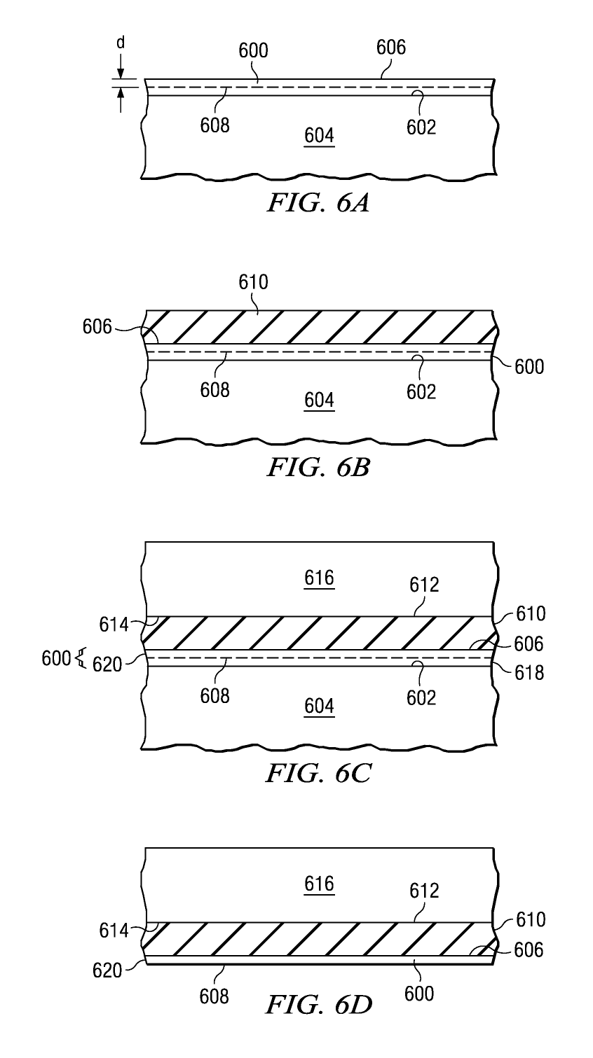

FIGS. 6A-6D illustrate a variation of this third fabrication process. Therein, a monocrystalline Group II-VI semiconductor layer 600, having any of several compositions as above described, is formed as by means of MBE or MOCVD on an upper surface 602 of a first substrate 604, which is selected for its suitability as a growth host for the Group II-VI semiconductor layer 600, for its mechanical robustness, and for its affordability. This is followed by an implantation step in which expungement ions, preferably comprising hydrogen, helium, other suitable ions or mixtures thereof, are implanted into the upper face 606 of the Group II-VI semiconductor layer 600. An implantation energy and dose are selected such that a maximum concentration of ions occurs at a preselected depth d below face 606. This maximum occupies a planar locus or horizon 608.

Next, any additional group II-VI semiconductor layers are added to layer 600 and as seen in FIG. 6B, a highly conductive layer 610 such as a heavily doped semiconductor, tunnel junction structure, silicide or metal is appended to the upper face 606 of the Group II-VI semiconductor layer 600. Then, as seen in FIG. 6C, an upper surface 612 of the highly conductive layer 610 is attached to a lower surface 614 of a second substrate 616, which may be preselected by the fabricator from a relatively wide range of choices.

After the second substrate 616 is affixed to a highly conductive layer 610, an expungement step is performed, such that all of first substrate 604 and a lower portion 618 of the Group II-VI semiconductor layer 600 is removed from an upper portion 620 of the Group II-VI semiconductor layer 600, from the highly conductive layer 610, and from the second substrate 616. The result is shown in FIG. 6D: a thin monocrystalline Group II-VI semiconductor layer 620, mounted to a fabricator-selected substrate 616 by means of the highly conductive layer, 610.

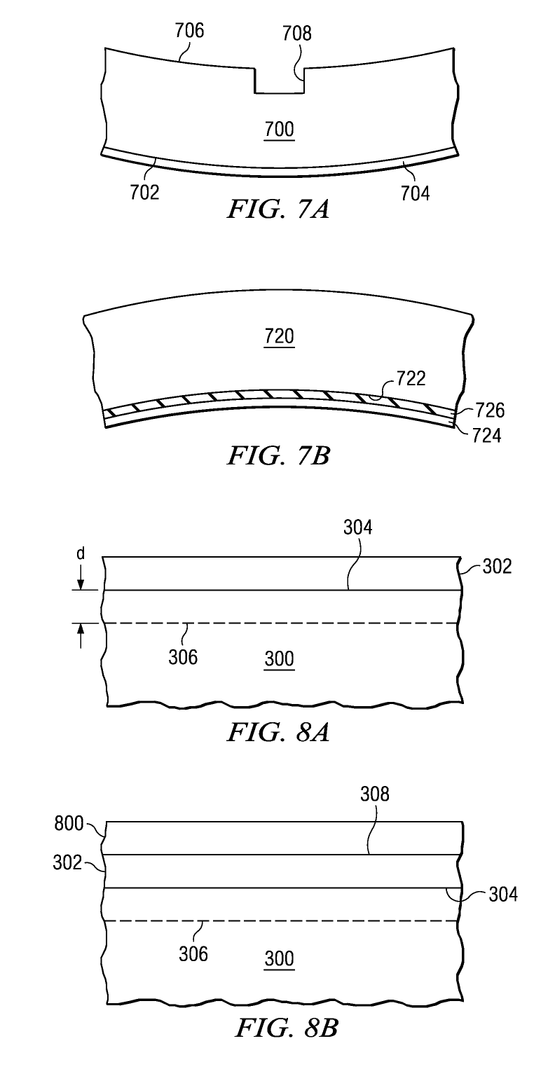

FIGS. 7A and 7B illustrate alternative embodiments of the produced mounted monocrystalline Group II-VI semiconductor structures, wherein the end or second substrate intentionally is not planar. In FIG. 7A, a preselected (second) substrate 700 is selected to have a lower convexly curved surface 702. A thin monocrystalline Group II-VI semiconductor layer 704 is thin enough to be able to conform to the curvature of surface 702. A back surface 706 of the substrate 700 doesn't have to conform in shape to the front surface 702, as shown by the occurrence of indentation 708, and the thickness of substrate 700 can be varied as desired.

FIG. 7B illustrates a case in which a (second, preselected) substrate 720 is chosen to have a front, concave surface 722. A thin monocrystalline Group II-VI semiconductor layer 724 is adhered to the surface 722 by means of a highly conductive layer 726, such as a heavily doped semiconductor, tunnel junction structure, silicide or metal.

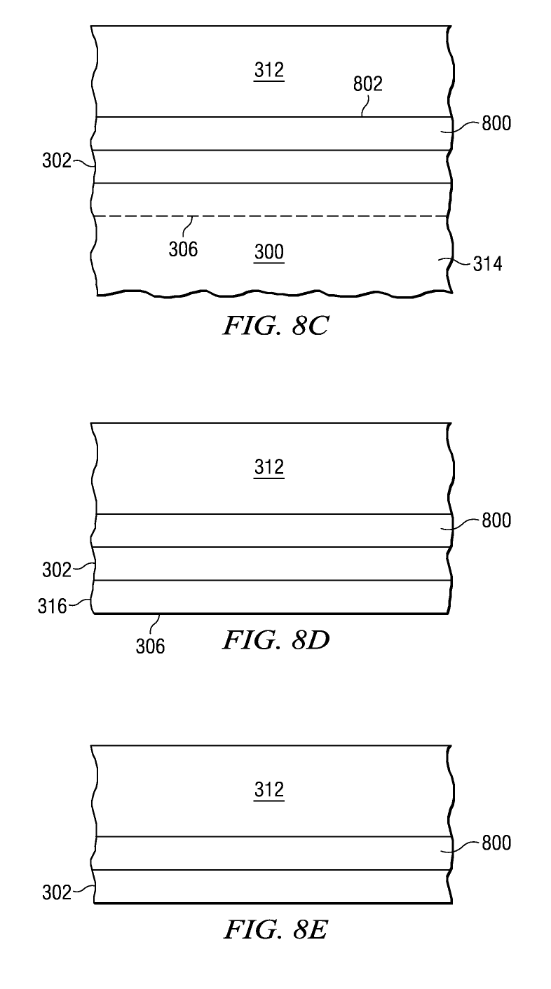

FIGS. 8A-8E illustrate a variation on the process shown in FIGS. 3A-3E. In FIG. 8A, an expungement ion implantation has been performed through Group II-VI semiconductor layer 302 such that a maximum concentration of the expungement ions will occur at plane or horizon 306, at a depth d below an upper surface 304 of substrate 300. Then (FIG. 8B) a further Group II-VI semiconductor layer 800 is grown or deposited on an upper surface 308 of the layer 302. The composition of layer 800 may be the same as layer 302, or it may be different. Layer 800 may be composed of various sublayers sequentially added to the workpiece. Alternatively, the composition of layer 800 can be continuously graded, and can for example have an initial composition adjacent surface 308 which matches layer 302, and a final composition which is quite different.

Following the formation of layer 800, a second substrate 312, of the user's choice and not being constrained by its compatibility as a nucleation site for Group II-VI material, is attached (FIG. 8C) by means previously described to an upper surface 802 of the layer 800. In the subsequent expungement step, the results of which are shown in FIG. 8D, a lower portion 314 of the first substrate 300 is expunged from an upper portion 316 thereof along plane or horizon 306. The first substrate remnant 316 may be used in further processing steps or (FIG. 8E) may be removed.

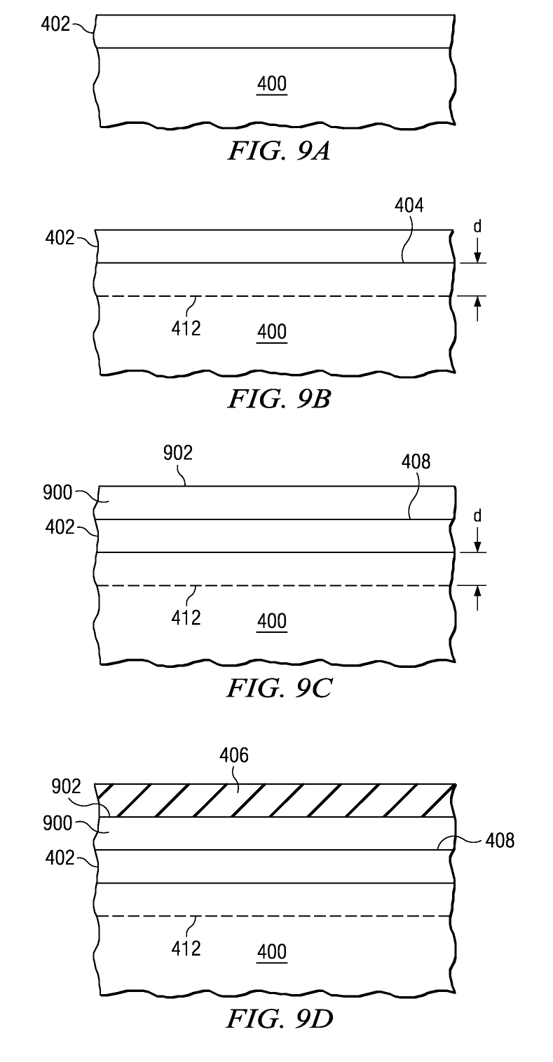

FIGS. 9A-9D illustrate a variation on the process shown in FIGS. 4A-4C. On a first substrate 400, which can be chosen for its suitability as a growth site for Group II-VI semiconductor material, a monocrystalline Group II-VI semiconductor layer 402 is formed. Expungement ions are implanted (FIG. 9B) through layer 402 with an energy and dose selected such that their concentration achieves a maximum at horizon 412. After this implantation step a further Group II-VI semiconductor layer 900 is grown or deposited on an upper surface 408 of the layer 402 (FIG. 9C). The composition of layer 900 can be the same as or different from the composition of layer 402. Layer 900 can, for example, be composed of sublayers (not shown) or can be continuously graded.

Next (FIG. 9D) a highly conductive layer 406 is formed on an upper surface 902 of the layer 900. The remaining steps in this embodiment are similar to those shown in FIGS. 8A-8E. The highly conductive layer 406 is used to attach the workpiece to a second substrate, an expungement step removes most of the first substrate, and optionally a remnant of the first substrate can also be removed.

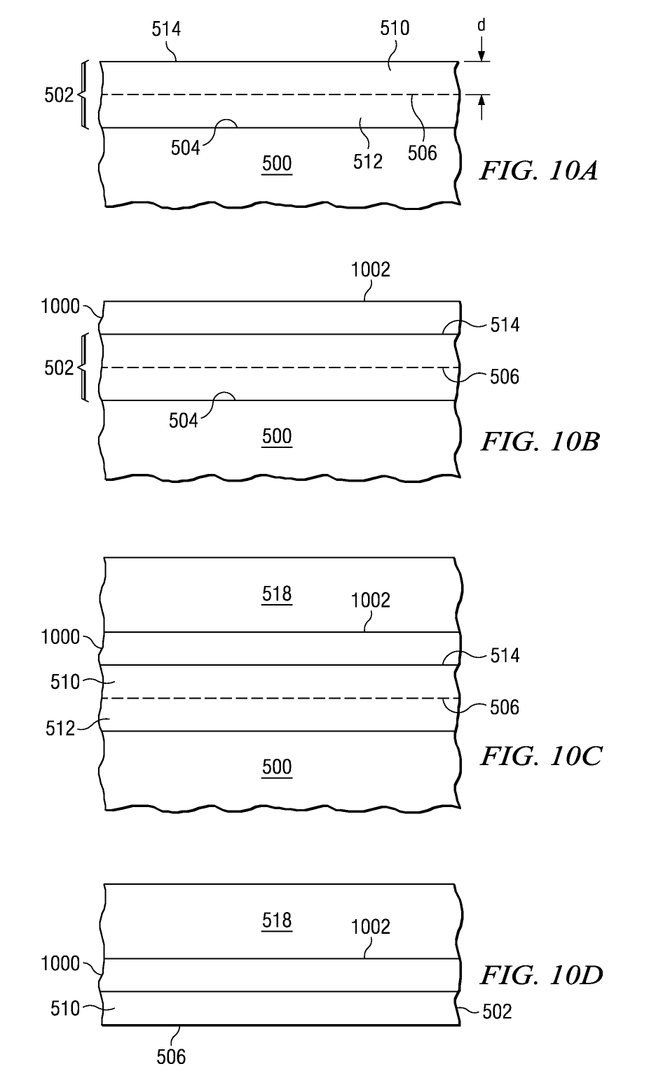

FIGS. 10A-10D illustrate a variation on the process shown in FIGS. 5A-5C. As before, and referring in particular to FIG. 10A, a monocrystalline Group II-VI semiconductor layer 502 is grown or otherwise formed on an upper surface 504 of a first substrate 500. Expungement ions are implanted through an upper surface 514 of the layer 502. The implantation energy and dose of the expungement ions are selected to achieve a maximum concentration of the ions at horizon or level 506, which in this embodiment remains within the Group II-VI layer 502 rather than first substrate 500. The level 506 is disposed at a preselected depth d from the upper surface 514 of layer 502.

After the implantation step a further Group II-VI semiconductor layer 1000 (FIG. 10B) is grown or deposited on the upper surface 514 of the layer 502. The composition of layer 1000 can be similar to or can be different from the composition of layer 502. Layer 1000 can be formed of sublayers (not shown) or can be continuously graded. Thereafter (FIG. 10C) a second substrate 518, the selection of which is unconstrained by its suitability as a Group II-VI semiconductor nucleation site, is attached by the means described herein to an upper surface 1002 of the Group II-VI layer 1000. In a subsequent expungement step (the results of which are shown in FIG. 10D), the entirety of the first substrate 500 and lower portion 512 of the layer 502 are expunged along horizon 506 from an upper portion 510 and the rest of the workpiece.

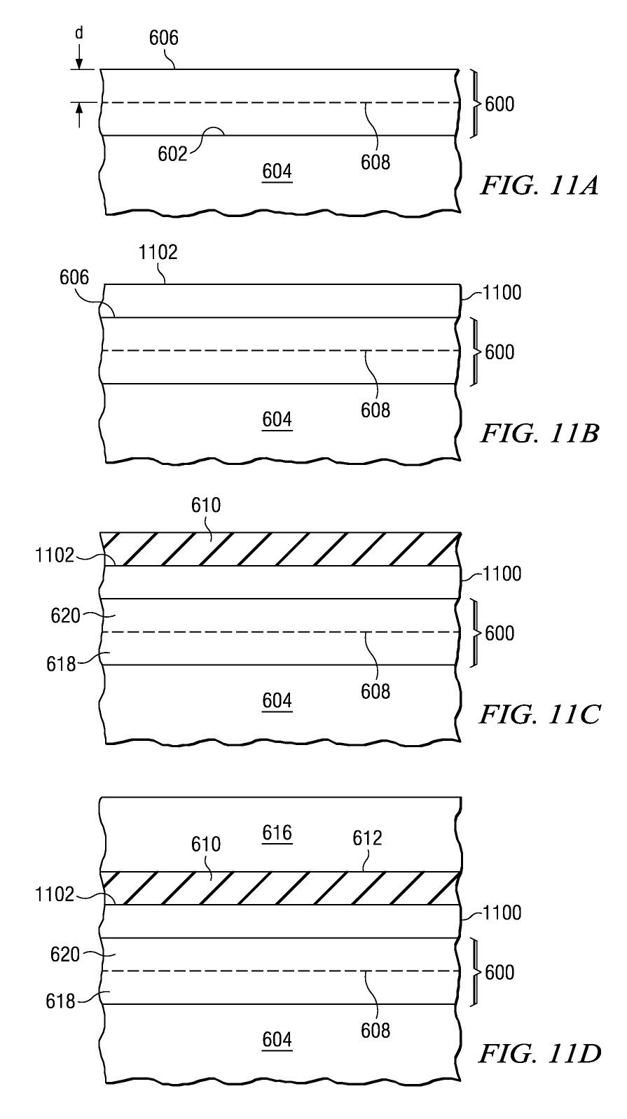

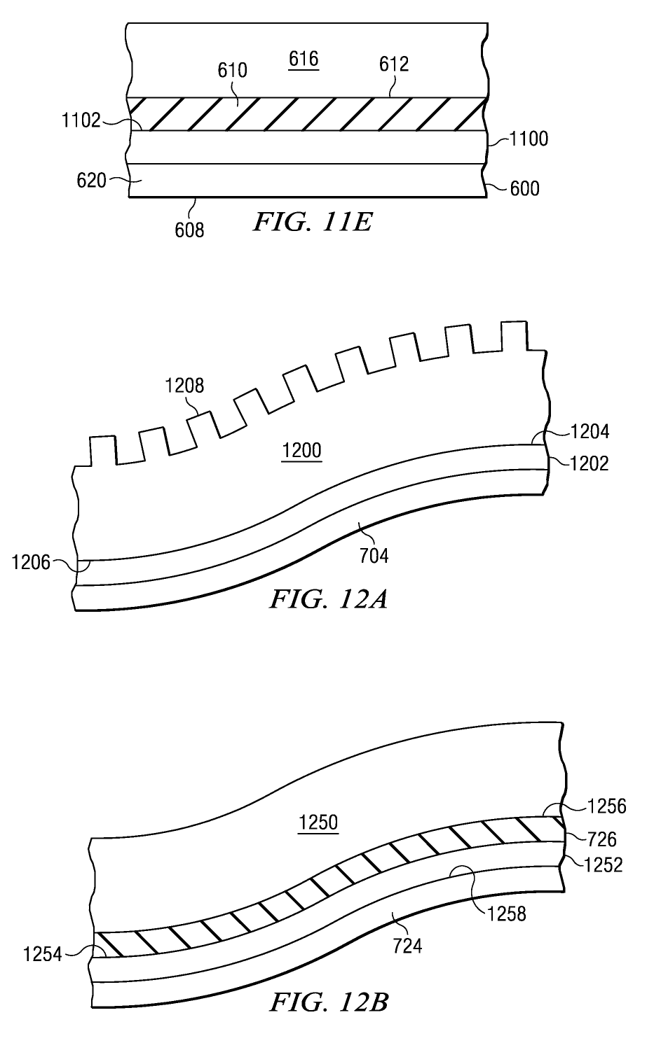

FIGS. 11A-11E illustrate a variation on the process shown in FIGS. 6A-6D. In this embodiment a first Group II-VI layer 600 is formed on an upper surface 602 of a first substrate 604. An expungement ion implantation is performed such that a maximum concentration of the expungement ions occurs at a depth d from upper surface 606 of the layer 600, at a level or horizon 608. After the implantation step (FIG. 11B) a further Group II-VI semiconductor layer 1100 is grown or otherwise formed on an upper surface 606 of the first Group II-VI layer 600. The composition of layer 1100 can be similar to or can be different from layer 600. Layer 1100, for example, can be continuously graded or be composed of sublayers (not shown).

After the completion of layer 1100 a highly conductive layer, 610, is formed on an upper surface 1102 of the layer 1100 (FIG. 11C). This layer 610 is used (FIG. 11D) to attach a second substrate 616 to the rest of the workpiece. After this attachment step an expungement step can be performed, the results of which are shown in FIG. 11E: all of first substrate 604, and a lower portion 618 of the initial Group II-VI semiconductor layer 600, is expunged from an upper portion 620 of layer 600, and from the layers 1100, 1102 and 616 attached to such upper portion 620.

FIGS. 12A and 12B illustrate further variations on structures produced by the above processes. In FIG. 12A, a second Group II-VI semiconductor layer 1202 has been grown or otherwise formed on the first Group II-VI semiconductor layer 704. An upper surface 1204 of the second Group II-VI layer 1202 is attached to a lower surface 1206 of a curved substrate 1200. The substrate 1200 can be recurved or complexly curved, as shown, and can be chosen to be flexible. A reverse surface 1208 of the substrate does not have to be smooth and in this illustrated embodiment has a periodic series of upwardly projecting ribs or serrations.

In FIG. 12B, a second Group II-VI semiconductor layer 1252 has been grown or otherwise formed on an upper surface 1258 of a first Group II-VI semiconductor layer 724. A highly conductive layer 726 has been formed on an upper surface 1254 of the second Group II-VI semiconductor layer 1252. The highly conductive layer 726 is in turn used to attach the monocrystalline semiconductor material to a lower surface 1256 of a substrate 1250. The substrate 1250 can be complexly curved, as shown, and can be chosen to be flexible.

The variations in compositions, doses, implantation energies, implantation depths and the like expressed for any of the above embodiments are largely applicable to the others. Thus, the first substrate can be elemental silicon, a silicon-germanium alloy, a silicon on insulator structure or other substrate selected for its ability to act as a host for the deposition of a Group II-VI semiconductor layer, for its relative robustness during the fabrication process, and preferably for its low cost. The Group II-VI semiconductor layer can be CdTe or any of a large number of other binary, ternary or even quaternary Group II-VI semiconductor compositions, or graded composites or multilayers of the foregoing. The second substrate can be any convenient material which will withstand the expungement step and can for example be chosen to be a semiconductor, integrated circuit, MEMS structure, a flexible polymer, metal or glass, and can be planar or singly or complexly curved. The ion cut techniques used can employ hydrogen ions or a combination of hydrogen, helium, and/or other suitable ions. In certain embodiments, a leftover remnant of the first substrate may be subsequently removed or may be left intact for further use in making discrete optoelectronic or other integrated circuits from the first substrate and/or the Group II-VI semiconductor layer which it masks.

In summary, ion cut techniques have been shown and described which produce thin monocrystalline Group II-VI semiconductor layers mounted on substrates of the fabricator's choice. While illustrated embodiments of the present invention have been described and illustrated in the appended drawings, the present invention is not limited thereto but only by the scope and spirit of the appended claims.

We claim:

1. A method for mounting a thin Group II-VI monocrystalline semiconductor layer to a preselected substrate, comprising the steps of:
implanting expungement ions into a first face of a first substrate such that a concentration of the implanted expungement ions achieves a maximum at a predetermined depth from the first face, the first substrate having a second face opposed to the first face;
growing a monocrystalline Group II-VI semiconductor layer on the first face of the first substrate, the Group II-VI semiconductor layer having a first face proximate to the first substrate and a second face remote from the first substrate;
attaching the second face of the Group II-VI semiconductor layer to a second, preselected substrate; and
using the expungement ions to expunge a portion of the first substrate extending from said depth to the second face thereof from a remainder of the first substrate extending from said depth to the first face of the first substrate, from the Group II-VI semiconductor layer, and from the second substrate.

2. The method of claim 1, wherein said step of using the expungement ions is performed by heating the first substrate.

3. The method of claim 1, wherein said step of using the expungement ions is performed by creating mechanical strain on the first substrate in a plane at said depth which is parallel to the first face of the first substrate.

4. The method of claim 1, wherein said depth is preselected from the range of about 100 nm to about 5,000 nm as measured from the first face of the first substrate.

5. The method of claim 4, wherein the expungement ions are implanted at an energy in the range of about 10 keV to about 300 keV and at a dose in the range of about 1×10¹⁶ ions/cm² to about 3×10¹⁷ ions/cm².

6. The method of claim 1, wherein the expungement ions include hydrogen, helium or hydrogen and helium.

7. The method of claim 1, wherein the first substrate is selected from the group consisting of monocrystalline Si, alloys of Si and Ge, silicon on insulator (SOI) structures, Group III-V compound semiconductors and Group II-VI compound semiconductors.

8. The method of claim 1, and further comprising the step of after said step using the expungement ions, removing said remainder of the first substrate from the Group II-VI semiconductor layer.

9. The method of claim 1, wherein the second substrate is a polymer, glass or metal.

10. The method of claim 1, wherein said step of attaching the second face of the Group II-VI semiconductor layer to the second substrate includes the further step of attaching the second face of the Group II-VI semiconductor layer to a curved surface of the second substrate.

11. The method of claim 1, wherein the Group II-VI semiconductor layer is selected from the group consisting of CdTe, CdZnTe, CdS, CdSe, ZnTe, ZnS, CdTeSe, CdMgTe, CdHgTe, graded composites of the foregoing and multilayers of the foregoing.

12. The method of claim 1, wherein the step of growing the Group II-VI semiconductor layer is performed by a molecular beam epitaxy process or MOCVD.

13. A method for mounting a thin Group II-VI monocrystalline semiconductor layer to a preselected substrate, comprising the steps of:
implanting expungement ions into a first face of a first substrate such that a concentration of the implanted expungement ions achieves a maximum at a predetermined depth from the first face, the first substrate having a second face opposed to the first face;
growing a monocrystalline Group II-VI semiconductor layer on the first face of the first substrate, the Group II-VI semiconductor layer having a first face proximate to the first substrate and a second face remote from the first substrate;
forming a highly conductive layer on the second face of the Group II-VI semiconductor layer;
appending the highly conductive layer to a second, preselected substrate; and
using the expungement ions to expunge a portion of the first substrate extending from said depth to the second face of the first substrate from a remainder of the first substrate extending from said depth to the first face of the first substrate, from the Group II-VI semiconductor layer, from the highly conductive layer and from the second substrate.

14. The method of claim 13, wherein the highly conductive layer is a heavily doped semiconductor, tunnel junction structure, silicide or metal.

15. The method of claim 13, wherein said step of using the expungement ions is performed by heating the first substrate.

16. The method of claim 13, wherein said step of using the expungement ions is performed by creating a mechanical strain at said depth in a plane parallel to the first face of the first substrate.

17. The method of claim 13, wherein said depth is preselected from the range of about 100 nm to about 5,000 nm.

18. The method of claim 13, wherein the ions are implanted at an energy in the range of about 10 keV to about 300 keV and at a dose in the range of about 1×10¹⁶ ions/cm² to about 3×10¹⁷ ions/cm².

19. The method of claim 13, wherein the expungement ions include hydrogen, helium or hydrogen and helium.

20. The method of claim 13, wherein the first substrate is a semiconductor selected from the group consisting of monocrystalline Si, alloys of Si and Ge, silicon on insulator (SOI) structures, Group III-V compound semiconductors and Group II-VI compound semiconductors.

21. The method of claim 13, and further comprising the step of
after said step using the expungement ions, removing said remainder of the first substrate from the Group II-VI semiconductor layer.

22. The method of claim 13, wherein the second substrate is a semiconductor, integrated circuit, MEMS structure, a polymer, metal or glass.

23. The method of claim 13, wherein the step of attaching the highly conductive layer to the second substrate includes the step of attaching the highly conductive layer to a curved surface of the second substrate.

24. The method of claim 13, wherein the Group II-VI semiconductor layer is selected from the group consisting of CdTe, CdZnTe, CdS, CdSe, ZnTe, ZnS, CdSeTe, CdMnTe, CdMgTe, CdHgTe, graded composites of the foregoing and multilayers of the foregoing.

25. The method of claim 13, wherein the step of growing the Group II-VI semiconductor layer is performed by a molecular beam epitaxy process or MOCVD.

26. A method for mounting a thin Group II-VI monocrystalline semiconductor layer to a preselected substrate, comprising the steps of:
growing a thin monocrystalline Group II-VI semiconductor layer on a first face of a first substrate, the first substrate having a second face opposed to the first face, the Group II-VI semiconductor layer having a first face proximate the first substrate and a second face remote from the first substrate;
implanting expungement ions through the second face of the Group II-VI semiconductor layer and through the first face of the first substrate, a dose and energy of the implantation preselected such that a maximum concentration of the expungement ions will occur at a predetermined depth in the first substrate as measured from the first face thereof,
attaching the second face of the Group II-VI semiconductor layer to a second, preselected substrate; and
using the expungement ions to expunge a portion of the first substrate which extends from said depth to the second face of the first substrate from a remainder of the first substrate extending from said depth to the first face of the first substrate, from the Group II-VI semiconductor layer, and from the second substrate.

27. The method of claim 26, wherein said step of using the expungement ions is performed by heating the first substrate.

28. The method of claim 26, wherein said step of using the expungement ions is performed by creating mechanical strain on the first substrate in a plane at said depth which is parallel to the first face of the first substrate.

29. The method of claim 26, wherein said depth is preselected from the range of about 100 nm to about 5,000 nm as measured from the first face of the first substrate.

30. The method of claim 26, wherein the ions are implanted at an energy in the range of about 10 keV to about 1.1 MeV and at a dose in the range of about 1×10¹⁶ ions/cm² to about 3×10¹⁷ ions/cm².

31. The method of claim 26, wherein the expungement ions include hydrogen, helium or hydrogen and helium.

32. The method of claim 26, wherein the first substrate is a semiconductor selected from the group consisting of monocrystalline Si, alloys of Si and Ge, silicon on insulator (SOI) structures, Group III-V compound semiconductors and Group II-VI compound semiconductors.

33. The method of claim 26, and further comprising the step of after said step using the expungement ions, removing said remainder of the first substrate from the Group II-VI semiconductor layer.

34. The method of claim 26, wherein the second substrate is a semiconductor, integrated circuit, MEMS structure, polymer, glass or metal.

35. The method of claim 26, wherein said step of attaching the second face of the Group II-VI semiconductor layer to the second substrate includes the step of attaching the second face of the Group II-VI semiconductor layer to a curved surface of the second substrate.

36. The method of claim 26, wherein the Group II-VI semiconductor layer is selected from the group consisting of CdTe, CdZnTe, CdS, CdSe, ZnTe, ZnS, CdSeTe, CdMgTe, CdMnTe, CdHgTe graded composites of the foregoing and multilayers of the foregoing.

37. The method of claim 26, wherein the step of growing the Group II-VI semiconductor layer is performed by a molecular beam epitaxy process or MOCVD.

38. A method for mounting a thin Group II-VI monocrystalline semiconductor layer to a preselected substrate, comprising the steps of:
growing a thin monocrystalline Group II-VI semiconductor layer on a face of a first substrate, the first substrate having a second face opposed to the first face thereof, the Group II-VI semiconductor layer having a first face proximate the first substrate and a second face remote from the first substrate;
implanting expungement ions through the second face of the Group II-VI semiconductor layer and through the face of the first substrate, a dose and energy of the implantation preselected such that a maximum concentration of the expungement ions will occur at a predetermined depth in the first substrate as measured from the first face of the first substrate;
depositing a highly conductive layer on the second face of the Group II-VI semiconductor layer;
attaching the highly conductive layer to a second, preselected substrate; and
using the expungement ions to expunge a portion of the first substrate extending from said depth to the second face of the first substrate from a remainder of the first substrate extending from said depth to the first face of the first substrate, from the Group II-VI semiconductor layer, from the highly conductive layer and from the second substrate.

39. The method of claim 38, wherein the highly conductive layer is a heavily doped semiconductor, tunnel junction structure, silicide or metal.

40. The method of claim 38, wherein said step of using the expungement ions is performed by heating the first substrate.

41. The method of claim 38, wherein said step of using the expungement ions is performed by creating a mechanical strain at said depth in a plane parallel to the first face of the first substrate.

42. The method of claim 38, wherein said depth is preselected from the range of about 100 nm to about 5,000 nm.

43. The method of claim 38, wherein the ions are implanted at an energy in the range of about 10 keV to about 1.1 MeV and at a dose in the range of about 1×10¹⁶ ions/cm² to about 3×10¹⁷ ions/cm².

44. The method of claim 38, wherein the expungement ions include hydrogen, helium or hydrogen and helium.

45. The method of claim 38, wherein the first substrate is a semiconductor selected from the group consisting of monocrystalline Si, alloys of Si and Ge, and silicon on insulator (SOI) structures.

46. The method of claim 38, and further comprising the step of
after said step using the expungement ions, removing said remainder of the first substrate from the Group II-VI semiconductor layer.

47. The method of claim 38, wherein the second substrate is a semiconductor, integrated circuit, MEMS structure, a polymer, glass or metal.

48. The method of claim 38, wherein said step of attaching the highly conductive layer to the second substrate includes the step of attaching the highly conductive layer to a curved surface of the second substrate.

49. The method of claim 38, wherein the Group II-VI semiconductor layer is selected from the group consisting of CdTe, CdZnTe, CdS, CdSe, ZnTe, ZnS, CdSeTe, CdMnTe, CdMgTe, CdHgTe, graded composites of the foregoing and multilayers of the foregoing.

50. The method of claim 38, wherein the step of growing the Group II-VI semiconductor layer is performed by a molecular beam epitaxy process or MOCVD.

51. A method for mounting a thin Group II-VI monocrystalline semiconductor layer to a preselected substrate, comprising the steps of:
growing a thin monocrystalline Group II-VI semiconductor layer on a face of a first substrate, the Group II-VI semiconductor layer having a first face proximate the first substrate and a second face remote from the first substrate;
implanting expungement ions into the second face of the Group II-VI semiconductor layer such that a concentration of the implanted ions achieves a maximum at a predetermined depth in the Group II-VI semiconductor layer as measured from the second face thereof, the predetermined depth being spaced from the first face of the Group II-VI semiconductor layer;
attaching the second face of the Group II-VI semiconductor layer to a second, preselected substrate; and
using the expungement ions to expunge a portion of the Group II-VI semiconductor layer adjacent the first face thereof and extending to said depth and the first substrate from a remainder of the Group II-VI semiconductor layer extending from said depth to said second face, and from the second substrate.

52. The method of claim 51, wherein said step of using the expungement ions is performed by heating the first substrate.

53. The method of claim 51, wherein said step of using the expungement ions is performed by creating a mechanical strain at said depth in a plane parallel to the first face of the first substrate.

54. The method of claim 51, wherein said depth is preselected from the range of about 10 nm to about 10,000 nm.

55. The method of claim 51, wherein the ions are implanted at an energy in the range of about 10 keV to about 1.1 MeV and at a dose in the range of about 1×10¹⁶ ions/cm² to about 3×10¹⁷ ions/cm².

56. The method of claim 51, wherein the expungement ions include hydrogen, helium or hydrogen and helium.

57. The method of claim 51 wherein the first substrate is a semiconductor selected from the group consisting of monocrystalline Si, alloys of Si and Ge, silicon on insulator (SOI) structures, Group III-V compound semiconductors and Group II-VI compound semiconductors.

58. The method of claim 51, wherein the second substrate is a semiconductor, integrated circuit, MEMS structure, a polymer, glass or metal.

59. The method of claim 51, wherein said step of attaching the second face of the Group II-VI semiconductor layer to the second substrate includes the step of attaching the second face of the Group II-VI semiconductor layer to a curved surface of the second substrate.

60. The method of claim 51, wherein the Group II-VI semiconductor layer is selected from the group consisting of CdTe, CdZnTe, CdS, CdSe, ZnTe, ZnS, CdSeTe, CdMnTe, CdMgTe, CdHgTe, graded composites of the foregoing and multilayers of the foregoing.

61. The method of claim 51, wherein the step of growing the Group II-VI semiconductor layer is performed by a molecular beam epitaxy process or MOCVD.

62. A method for mounting a thin Group II-VI monocrystalline semiconductor layer to a preselected substrate, comprising the steps of:
growing a thin monocrystalline Group II-VI semiconductor layer on a face of a first substrate, the Group II-VI semiconductor layer having a first face proximate the first substrate and a second face remote from the first substrate;
implanting expungement ions into the second face of the Group II-VI semiconductor layer such that a concentration of the implanted expungement ions achieves a maximum at a predetermined depth in the Group II-VI semiconductor layer as measured from the second face thereof, the predetermined depth being spaced from the first face of the Group II-VI semiconductor layer; depositing a highly conductive layer on the second face of the Group II-VI semiconductor layer; attaching the highly conductive layer to a second, preselected substrate; and
using the expungement ions to expunge a portion of the Group II-VI semiconductor layer adjacent the first face thereof and extending to said depth and the first substrate from a remainder of the Group II-VI semiconductor layer extending from said depth to said second face, from the highly conductive layer, and from the second substrate.

63. The method of claim 62, wherein the highly conductive layer is a heavily doped semiconductor, tunnel junction structure, silicide or metal.

64. The method of claim 62, wherein said step of using the expungement ions is performed by heating the first substrate.

65. The method of claim 62, wherein said step of using the expungement ions is performed by creating a mechanical strain at said depth in a plane parallel to the first face of the first substrate.

66. The method of claim 62, wherein said depth is preselected from the range of about 10 nm to about 10,000 nm.

67. The method of claim 62, wherein the expungement ions are implanted at an energy in the range of about 10 keV to about 1.1 MeV and at a dose in the range of about 1×10¹⁶ ions/cm² to about 3×10¹⁷ ions/cm².

68. The method of claim 62, wherein the expungement ions include hydrogen, helium or hydrogen and helium.

69. The method of claim 62, wherein the first substrate is a semiconductor selected from the group consisting of monocrystalline Si, alloys of Si and Ge, silicon on insulator (SOI) structures, Group III-V compound semiconductors and Group II-VI compound semiconductors.

70. The method of claim 62, wherein the second substrate is a semiconductor, integrated circuit, MEMS structure, a polymer, glass or metal.

71. The method of claim 62, wherein said step of attaching the highly conductive layer to the second substrate includes the step of attaching the highly conductive layer to a curved surface of the second substrate.

72. The method of claim 62, wherein the Group II-VI semiconductor layer is selected from the group consisting of CdTe, CdZnTe, CdS, CdSe, ZnTe, ZnS, CdSeTe, CdMnTe, CdMgTe, CdHgTe, graded composites of the foregoing and multilayers of the foregoing.

73. The method of claim 62, wherein the step of growing the Group II-VI semiconductor layer is performed by a molecular beam epitaxy process or MOCVD.

74. A method for mounting a Group II-VI monocrystalline semiconductor to a preselected substrate, comprising the steps of:
growing a first monocrystalline Group II-VI semiconductor layer on a first face of a first substrate, the first substrate having a second face opposed to the first face, the first Group II-VI semiconductor layer having a first face proximate the first substrate and a second face remote from the first substrate;
implanting expungement ions through the second face of the first Group II-VI semiconductor layer and through the first face of the first substrate, a dose and energy of the implantation preselected such that a maximum concentration of the expungement ions will occur at a predetermined depth in the first substrate as measured from the first face thereof,
forming a second Group II-VI semiconductor layer on the second face of the first Group II-VI semiconductor layer, such that the second semiconductor layer has a first face proximate the first Group II-VI semiconductor layer and a second face remote from the first Group II-VI semiconductor layer;
attaching the second face of the second Group II-VI semiconductor layer to a second, preselected substrate; and
using the expungement ions to expunge a portion of the first substrate which extends from said depth to the second face of the first substrate from a remainder of the first substrate extending from said depth to the first face of the first substrate, from the Group II-VI semiconductor layers, and from the second substrate.

75. A method for mounting a Group II-VI monocrystalline semiconductor to a preselected substrate, comprising the steps of:
growing a first monocrystalline Group II-VI semiconductor layer on a face of a first substrate, the first substrate having a second face opposed to the first face thereof, the first Group II-VI semiconductor layer having a first face proximate the first substrate and a second face remote from the first substrate;
implanting expungement ions through the second face of the first Group II-VI semiconductor layer and through the face of the first substrate, a dose and energy of the implantation preselected such that a maximum concentration of the expungement ions will occur at a predetermined depth in the first substrate as measured from the first face of the first substrate;
forming a second Group II-VI semiconductor layer on the second face of the first Group II-VI semiconductor layer, the second Group II-VI semiconductor layer having a first face proximate the first face of the first Group II-VI semiconductor layer and a second face remote therefrom;
appending a highly conductive layer on the second face of the second Group II-VI semiconductor layer;
appending the highly conductive layer to a second, preselected substrate; and
using the expungement ions to expunge a portion of the first substrate extending from said depth to the second face of the first substrate from a remainder of the first substrate extending from said depth to the first face of the first substrate, from the first and second Group II-VI semiconductor layers, from the highly conductive layer and from the second substrate.

76. A method for mounting a Group II-VI monocrystalline semiconductor to a preselected substrate, comprising the steps of:
growing a first monocrystalline Group II-VI semiconductor layer on a face of a first substrate, the first Group II-VI semiconductor layer having a first face proximate the first substrate and a second face remote from the first substrate;
implanting expungement ions into the second face of the first Group II-VI semiconductor layer such that a concentration of the implanted ions achieves a maximum at a predetermined depth in the first Group II-VI semiconductor layer as measured from the second face thereof, the predetermined depth being spaced from the first face of the first Group II-VI semiconductor layer;
forming a second Group II-VI semiconductor layer on the first Group II-VI semiconductor layer, the second Group II-VI semiconductor layer having a first face proximate the second face of the first Group II-VI semiconductor layer and a second face remote therefrom;
attaching the second face of the second Group II-VI semiconductor layer to a second, preselected substrate; and
using the expungement ions to expunge a portion of the first Group II-VI semiconductor layer adjacent the first face thereof and extending to said depth and the first substrate from a remainder of the first Group II-VI semiconductor layer extending from said depth to said second face, from the second Group II-VI semiconductor layer, and from the second substrate.

77. A method for mounting a Group II-VI monocrystalline semiconductor to a preselected substrate, comprising the steps of:
growing a first monocrystalline Group II-VI semiconductor layer on a face of a first substrate, the first Group II-VI semiconductor layer having a first face proximate the first substrate and a second face remote from the first substrate;
implanting expungement ions into the second face of the first Group II-VI semiconductor layer such that a concentration of the implanted expungement ions achieves a maximum at a predetermined depth in the first Group II-VI semiconductor layer as measured from the second face thereof, the predetermined depth being spaced from the first face of the first Group II-VI semiconductor layer;
forming a second Group II-VI semiconductor layer on the second face of the first Group II-VI semiconductor layer, the second Group II-VI semiconductor layer having a first face proximate the second face of the first Group II-VI semiconductor layer and a second face remote therefrom;
depositing a highly conductive layer on the second face of the second Group II-VI semiconductor layer;
attaching the highly conductive layer to a second, preselected substrate; and
using the expungement ions to expunge a portion of the first Group II-VI semiconductor layer adjacent the first face thereof and extending to said depth and the first substrate from a remainder of the first Group II-VI semiconductor layer extending from said depth to said second face, from the second Group II-VI semiconductor layer, from the highly conductive layer, and from the second substrate.

78. A mounted semiconductor structure, comprising:
a polymer substrate; and
a monocrystalline Group II-VI semiconductor layer bonded to the polymer substrate and having a thickness of no more than 10,000 nm.

79. The mounted semiconductor structure of claim 74, wherein the Group II-VI semiconductor layer is selected from the group consisting of CdTe, CdZnTe, CdS, CdSe, ZnTe, ZnS, CdSeTe, CdMnTe, CdMgTe, CdHgTe, graded composites of the foregoing and multilayers of the foregoing.

80. The mounted semiconductor structure of claim 74, wherein the structure is flexible.

81. The mounted semiconductor structure of claim 74, wherein the Group II-VI semiconductor layer is bonded to a curved surface of the substrate.

82. A mounted semiconductor structure, comprising:
a polymer substrate;
a highly conductive layer attached to the polymer substrate; and
a monocrystalline Group II-VI semiconductor layer adjoining the highly conductive layer, wherein the Group II-VI semiconductor layer has a thickness of no more than 10,000 nm.

83. The mounted semiconductor structure of claim 78, wherein the Group II-VI semiconductor layer is selected from the group consisting of CdTe, CdZnTe, CdS, CdSe, ZnTe, ZnS, CdSeTe, CdMnTe, CdMgTe, CdHgTe, graded composites of the foregoing and multilayers of the foregoing.

84. The mounted semiconductor structure of claim 78, wherein the structure is flexible.

85. The mounted semiconductor structure of claim 78, wherein the highly conductive layer is appended to a curved surface of the substrate.
